(19) United States
(12) Patent Application Publication
(10) Pub. No.: US 2026/0173981 A1
(43) Pub. Date: Jun. 18, 2026

(54) MODULE AND METHOD OF MANUFACTURING THE SAME

(71) Applicant: Murata Manufacturing Co., Ltd., Nagaokakyo-shi (JP)

(72) Inventors: Kyo SHIN, Nagaokakyo-shi (JP); Yoshitaka MATSUKAWA, Nagaokakyo-shi (JP); Yoshihisa MASUDA, Nagaokakyo-shi (JP); Yosuke MINO, Nagaokakyo-shi (JP)

(73) Assignee: Murata Manufacturing Co., Ltd., Nagaokakyo-shi (JP)

(21) Appl. No.: 19/533,543

(22) Filed: Feb. 9, 2026

Related U.S. Application Data
(63) Continuation of application No. PCT/JP2024/034663, filed on Sep. 27, 2024.

(30) Foreign Application Priority Data
Nov. 16, 2023 (JP) 2023-195205

(51) Int. Cl. H10W 90/00; H10W 42/20; H10W 70/04; H10W 74/01; H10W 74/10; H10W 90/22

(52) U.S. Cl. CPC H10W 90/7295; H10W 42/276; H10W 70/041; H10W 74/01; H10W 90/22; H10W 74/117; H10W 90/724

(57) ABSTRACT

A method of manufacturing a module includes mounting a component including a silicon (Si) layer over a first substrate surface having a conductive connection structure arranged thereon. A sealing resin layer is formed to cover the first substrate surface, the conductive connection structure, and the component. A first exposed surface is formed by grinding the sealing resin layer, the conductive connection structure, and the component until respective portions of the conductive connection structure and the component are exposed through the sealing resin layer. Finishing processing is performed on the first exposed surface to decrease surface roughness Ra of the component. Plating on a surface of the conductive connection structure at the first exposed surface while the Si layer remains exposed and free of a resist film.

### CROSS-REFERENCE TO RELATED APPLICATIONS

This application is a continuation of PCT/JP2024/034663, filed Sep. 27, 2024, which claims priority to Japanese Patent Application No. 2023-195205, filed Nov. 16, 2023. The entire contents of each of the above-referenced applications are incorporated herein by reference.

### TECHNICAL FIELD

The present disclosure relates to a module and a method of manufacturing the same.

### BACKGROUND ART

A module with a structure in which an electronic component, such as an IC, is mounted over a substrate and sealed with sealing resin is known. The electronic component has a thick Si layer on the opposite side of the side on which it faces the substrate. In such a module, a structure may be employed in which a surface of the Si layer of the electronic component is exposed through the sealing resin. An example of the module with such a structure is described in Japanese Patent No. 6,981,537 (PTL 1). When such a module is manufactured, grinding processing is collectively performed on the sealing resin and the Si layer of the electronic component so that the upper surface of the sealing resin and the upper surface of the electronic component are made coplanar.

### CITATION LIST

### Patent Literature

PTL 1: Japanese Patent No. 6981537

### SUMMARY

A method of manufacturing a module includes: mounting a component including a Si layer over a first substrate surface of a substrate having the first substrate surface on which a conductive connection structure is arranged; forming a sealing resin layer so as to cover the first substrate surface, the conductive connection structure, and the component; forming a first exposed surface including respective portions where the conductive connection structure and the component are exposed through the sealing resin layer by collectively grinding away an upper surface of the conductive connection structure, an upper surface of the component, and an upper surface of the sealing resin layer by grinding processing; performing finishing processing on the first exposed surface to decrease surface roughness Ra of the component; and performing plating on a surface of the conductive connection structure at the first exposed surface.

### BRIEF DESCRIPTION OF DRAWINGS

FIG. 1 is a flowchart of a method of manufacturing a module according to a first embodiment based on the present invention.

FIG. 2 is an explanatory view of a first step in the method of manufacturing the module according to the first embodiment based on the present invention.

FIG. 3 is an explanatory view of a second step in the method of manufacturing the module according to the first embodiment based on the present invention.

FIG. 4 is a cross-sectional view of a component mounted over a first substrate surface by the method of manufacturing the module according to the first embodiment based on the present invention.

FIG. 5 is an explanatory view of a third step in the method of manufacturing the module according to the first embodiment based on the present invention.

FIG. 6 is an explanatory view of a fourth step in the method of manufacturing the module according to the first embodiment based on the present invention.

FIG. 7 is an explanatory view of a fifth step in the method of manufacturing the module according to the first embodiment based on the present invention.

FIG. 8 is an explanatory view of a sixth step in the method of manufacturing the module according to the first embodiment based on the present invention.

FIG. 9 is an explanatory view of a seventh step in the method of manufacturing the module according to the first embodiment based on the present invention.

FIG. 10 is an explanatory view of an eighth step in the method of manufacturing the module according to the first embodiment based on the present invention.

FIG. 11 is an explanatory view of a ninth step in the method of manufacturing the module according to the first embodiment based on the present invention.

FIG. 12 is an explanatory view of a tenth step in the method of manufacturing the module according to the first embodiment based on the present invention.

FIG. 13 is a cross-sectional view of the module according to the first embodiment based on the present invention.

FIG. 14 is a cross-sectional view of a module according to a second embodiment based on the present invention.

### DESCRIPTION OF EMBODIMENTS

In modules where a sealing resin and a silicon (Si) layer are collectively ground to expose a surface, the inventor has observed that the grinding processing often leaves grinding flaws, such as micro-cracks or deep striations, on the Si surface. These grinding flaws significantly increase the arithmetic mean roughness (Ra) of the Si layer.

Furthermore, the inventor has discovered a technical problem where, during a subsequent plating process, plating material tends to deposit and grow within these grinding flaws on the Si surface. This unintended plating growth can lead to electrical shorts, reduced structural integrity, and failures in crack detection. Conventionally, to prevent this, a resist film must be applied to the Si surface before plating.

The inventor has found that by performing a finishing process (e.g., CMP) after the collective grinding to reduce the surface roughness Ra of the Si layer, the plating growth on the Si surface is suppressed. Consequently, the plating process can be performed while the Si layer remains exposed and free of a resist film, simplifying the manufacturing process and improving module reliability. For example, providing a resist film for covering the upper surface of the component during plating is not needed, allowing forming a resist film and subsequent removal of the resist film to be eliminated.

Accordingly, the present disclosure is directed to providing a module and a method of manufacturing the same that enable the number of steps for the manufacture to be reduced while providing a module with improved reliability.

### First Embodiment

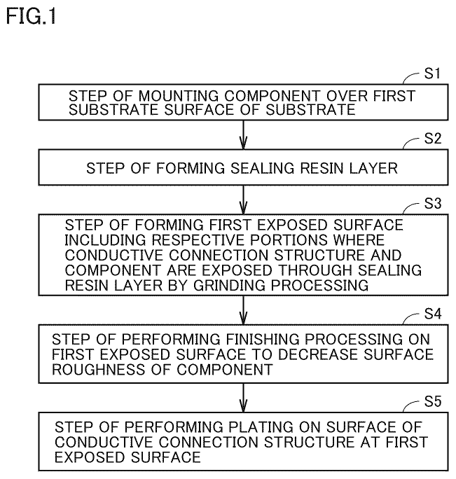

A method of manufacturing a module according to a first embodiment based on the present invention is described with reference to FIGS. 1 to 13. FIG. 1 is a flowchart of the method of manufacturing a module according to the present embodiment.

The method of manufacturing a module according to the present embodiment includes: a step S1 of mounting a component including a Si layer over a first substrate surface of a substrate having the first substrate surface on which a conductive connection structure is arranged; a step S2 of forming a sealing resin layer so as to cover the first substrate surface, the conductive connection structure, and the component; a step S3 of forming a first exposed surface including respective portions where the conductive connection structure and the component are exposed through the sealing resin layer by collectively grinding away an upper surface of the conductive connection structure, an upper surface of the component, and an upper surface of the sealing resin layer by grinding processing; a step S4 of performing finishing processing on the first exposed surface to decrease surface roughness Ra of the component; and a step S5 of performing plating on a surface of the conductive connection structure at the first exposed surface.

Each step is described in detail below. In practice, each step up to singulation is performed on a large-sized substrate corresponding to a state in which a plurality of modules are arranged, but here, for convenience of explanation, a portion corresponding to a single module is focused on and described while illustrated in the drawings.

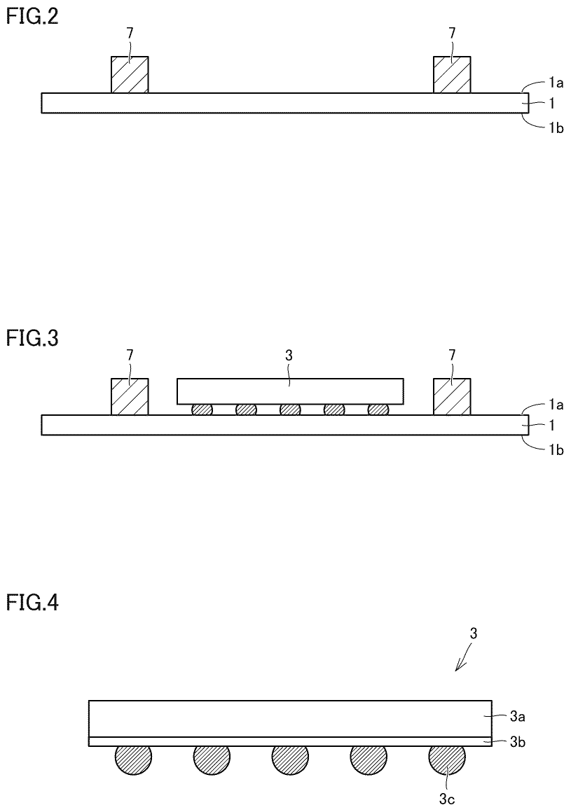

Firstly, a substrate 1 is prepared as illustrated in FIG. 2. Substrate 1 is, for example, a low temperature co-fired ceramics (LTCC) substrate. A material of which substrate 1 is formed may be a material that can be used as a circuit board material, such as glass or resin. Alternatively, substrate 1 may be formed of a composite material, such as glass epoxy. Substrate 1 has a first substrate surface 1a and a second substrate surface 1b opposite to each other. In FIG. 2, the upper surface is first substrate surface 1a and the lower surface is second substrate surface 1b. It is assumed here in the description, for convenience of explanation, that first substrate surface 1a is the upper surface but the orientation is not limited to this. A columnar electrode 7 used as a conductive connection structure is provided on first substrate surface 1a. Here, a columnar electrode is described as an example of the conductive connection structure, but the conductive connection structure is not limited to the columnar shape. The conductive connection structure may be, for example, a solder bump. The conductive connection structure may have a hemispherical shape for example. The conductive connection structure can be formed by a known technique. For example, when substrate 1 is an LTCC substrate, the conductive connection structure may be formed as sintered metal co-fired with the LTCC substrate. The conductive connection structure may be formed by causing plating growth on the substrate electrode. The conductive connection structure may be formed by mounting a metal structure, such as a pin, on a substrate electrode and performing solder connection. The conductive connection structure may be formed as a metal bump by melting a low melting point material, such as solder, on a substrate electrode. Any known material that is usable for electrical connection can be employed as the material of which the conductive connection structure is formed. The material of the conductive connection structure may be a conductive metal material, such as Cu, or may be an alloy material, such as solder. When the conductive connection structure is, for example, columnar electrode 7, the conductive connection structure may be in the form of a bulk made of a single material or may be in the form where a coating layer is formed on the outer surface of a main body portion serving as a core.

In step S1, as illustrated in FIG. 3, a component 3 is mounted over first substrate surface 1a. Component 3 is an electronic component. Component 3 is, for example, an integrated circuit (IC). As illustrated in FIG. 4, component 3 includes a wiring layer 3b and an electrode 3c connected to wiring layer 3b on the lower side. When component 3 is a SiIC, component 3 includes a Si layer 3a on the upper side. Si layer 3a is sufficiently thick in comparison with wiring layer 3b. Component 3 may be a component with a structure where a component function part is formed in a portion corresponding to wiring layer 3b in FIG. 4. More specifically, component 3 may be any one of a surface acoustic wave device, a bulk acoustic wave device, a passive integrated device, and the like.

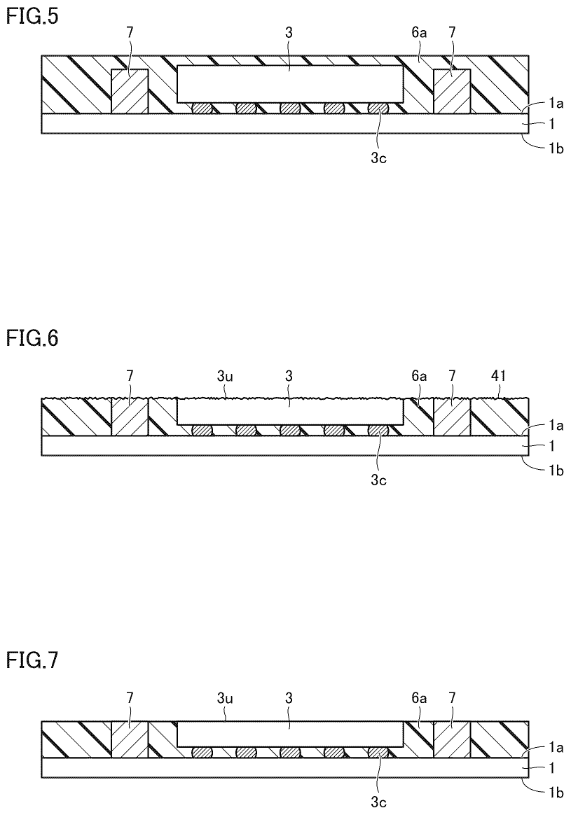

In step S2, as illustrated in FIG. 5, a sealing resin layer 6a is formed. Sealing resin layer 6a can be formed by a known technique, such as liquid resin coating, sheet resin molding, injection molding, transfer molding, or compression molding. First substrate surface 1a, component 3, and columnar electrode 7 are covered with sealing resin layer 6a.

In step S3, grinding processing is performed on the upper surface in FIG. 5. As the grinding processing, a known technique can be employed, such as plunge grinding, traverse grinding, in-feed grinding, or creep-feed grinding. By this grinding processing, as illustrated in FIG. 6, the upper surface of columnar electrode 7, the upper surface of component 3, and the upper surface of sealing resin layer 6a are collectively ground away. At the timing at which the grinding processing is complete, the upper surface of columnar electrode 7, the upper surface of component 3, and the upper surface of sealing resin layer 6a are positioned in the same plane. The whole of the surface formed by the grinding processing becomes a first exposed surface. That is, the entire upper surface in FIG. 6 is the first exposed surface. The first exposed surface includes the upper surface of columnar electrode 7, the upper surface of component 3, and the upper surface of sealing resin layer 6a. In the first exposed surface, a cross section of Si layer 3a is exposed as the upper surface of component 3. This exposed surface is a Si surface 3u. At this timing, a grinding flaw caused by the grinding processing is present on Si surface 3u.

In step S4, finishing processing is performed on the first exposed surface to decrease surface roughness Ra of component 3. Hereinafter, when “surface roughness” is simply mentioned, it means surface roughness Ra, that is, arithmetic mean roughness. As the finishing processing, specifically, chemical mechanical polishing (CMP) processing is performed. Consequently, as illustrated in FIG. 7, the surface roughness of component 3, that is, the surface roughness of Si surface 3u is decreased. As a result of this finishing processing, not only the surface roughness of component 3 but also the roughness of the surface other than the surface of component 3 may be decreased at the same time. For example, the finishing processing is performed so that the surface roughness of Si surface 3u becomes 0.001 μm or more and 0.1 μm or less. On the other hand, the surface roughness of the upper surface of sealing resin layer 6a is, for example, 0.05 μm or more and 0.1 μm or less as a result of the finishing processing. The grinding flaws caused on Si surface 3u by the grinding processing in step S3 are removed through the finishing processing in step S4.

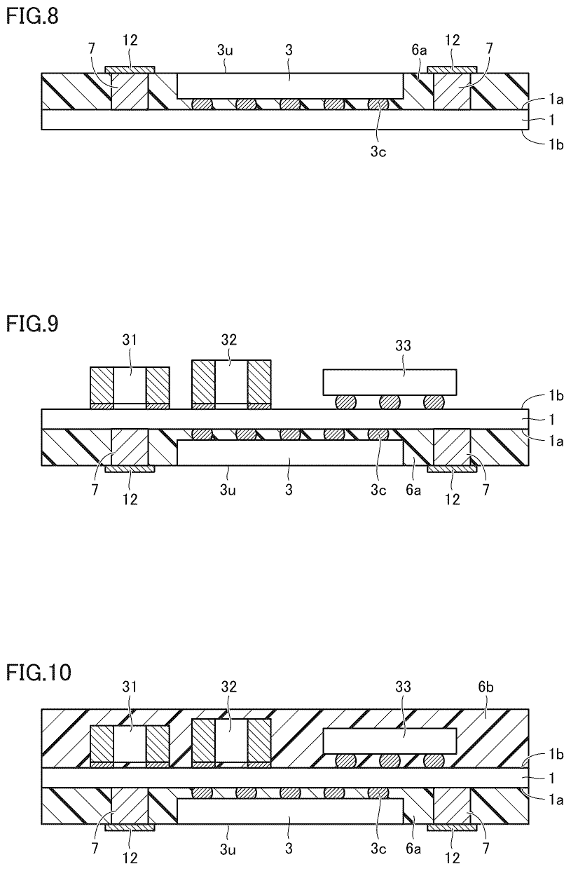

In step S5, a plating process is performed on the surface of columnar electrode 7 at the first exposed surface. The plating process can be performed by a known technique. When the plating process is performed, Si surface 3u may remain exposed. It is unnecessary to cover Si surface 3u with a resist film. As a result of performing the plating process, as illustrated in FIG. 8, a plating film 12 is formed so as to cover an end surface of columnar electrode 7. Plating film 12 may have a structure in which a plurality of layers are stacked. Plating film 12 may have, for example, a two-layer structure.

Furthermore, as illustrated in FIG. 9, the upper and lower sides are inverted and components 31, 32, and 33 are mounted over second substrate surface 1b.

As illustrated in FIG. 10, a sealing resin layer 6b is formed. Second substrate surface 1b and components 31, 32, and 33 are covered with sealing resin layer 6b.

As illustrated in FIG. 11, a bump 14 is formed. Although the end surface of columnar electrode 7 is already covered with plating film 12, bump 14 is formed so as to further cover plating film 12.

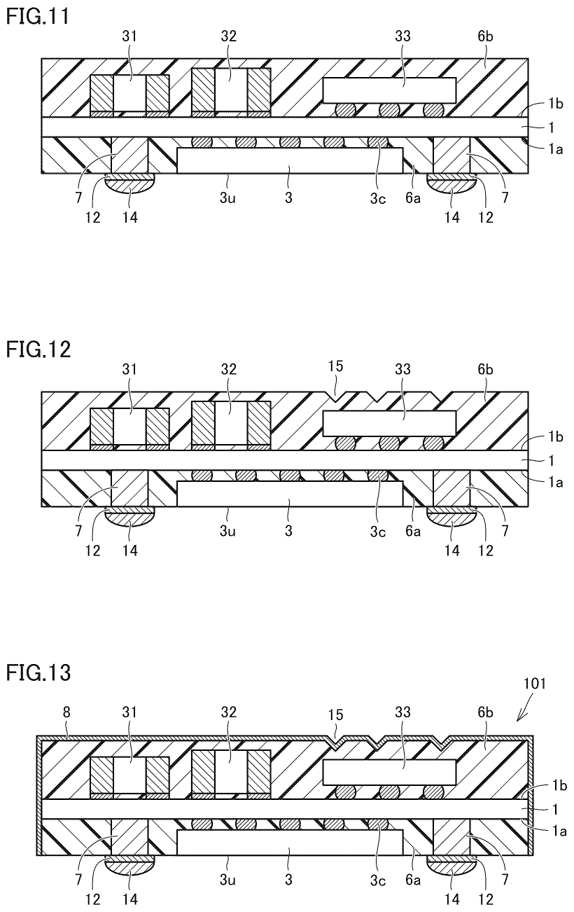

As illustrated in FIG. 12, printing is performed. This printing can be performed by a known technique, such as laser processing. In the case of laser processing, a depressed portion 15 is formed in the upper surface of sealing resin layer 6b as a result of the printing. Furthermore, singulation is performed. When the foregoing steps are performed on a large-sized substrate corresponding to a plurality of modules, the substrate is divided, after the printing, into individual modules according to their size.

As illustrated in FIG. 13, a shield film 8 is formed. Shield film 8 can be formed by a known technique, such as conductive resin coating, plating, vapor deposition, or sputtering. Shield film 8 is formed so as to cover the upper surface and the side surfaces of sealing resin layer 6b, the side surfaces of substrate 1, and the side surfaces of sealing resin layer 6a. In depressed portion 15 formed by the printing, shield film 8 is formed so as to cover the inner surface of depressed portion 15. In this manner, module 101 is obtained. In some embodiments, one or more of the at least two conductive connection structures (e.g., columnar electrodes 7) may serve as a ground terminal. The shield film 8 may be electrically connected to this ground potential via the plating film 12 or 41 on the end surface of the conductive connection structure. This electrical path provides electromagnetic interference (EMI) shielding for the electronic component 3, specifically when the component is a high-frequency device such as a surface acoustic wave device or a bulk acoustic wave device.

As illustrated in FIG. 13, module 101 according to the present embodiment includes substrate 1 having first substrate surface 1a, columnar electrode 7 as the conductive connection structure arranged on first substrate surface 1a, component 3 mounted over first substrate surface 1a, and sealing resin layer 6a provided so as to cover first substrate surface 1a, the side surfaces of columnar electrode 7, and the side surfaces of component 3. The end surface of columnar electrode 7 on the side farther from substrate 1 and the surface of component 3 on the side farther from substrate 1 are exposed through sealing resin layer 6a, and surface roughness Ra of the surface of component 3 on the side farther from substrate 1 is 0.1 μm or less.

When Si surface 3u has grinding flaws, Cu ions, a plating solution, and the like are likely to remain in the gaps of the grinding flaws, and plating deposition occurs, starting from the grinding flaws. In the manufacturing method according to the present embodiment, the finishing processing to decrease the surface roughness of the surface of component 3, that is, Si surface 3u is performed and the grinding flaws caused on Si surface 3u are removed in step S4, and thus, a plating film does not grow on Si surface 3u even when the plating process is performed in step S5. The inventor has observed that by performing the finishing processing to reduce the roughness to Ra 0.1 μm or less, the specific micro-cracks and striations that facilitate unintended metal deposition are removed. Consequently, the plating growth is suppressed to a degree that allows for plating to be performed while the Si surface remains exposed and free of a resist film. Accordingly, a resist film for covering Si surface 3u during the plating process is not needed. The step of forming a resist film and the step of removing the resist film can be dispensed with, reducing the number of steps.

The surface roughness of Si surface 3u after the completion of step S4 may be 0.005 μm or less, that is, 5 nm or less.

As shown in the present embodiment, step S4 of performing the finishing processing may include the step of performing CMP processing. Thus, it is enabled to decrease the surface roughness of Si surface 3u.

Surface roughness Ra of the surface of component 3 exposed through sealing resin layer 6a after the completion of step S4 of performing the finishing processing may be 0.1 μm or less. Thus, it is enabled to avoid the deposition of the plating film on Si surface 3u more reliably.

Surface roughness Ra of the upper surface of sealing resin layer 6a after the completion of step S4 of performing the finishing processing may be preferably 0.1 μm or less. Thus, it is enabled to make the appearance favorable.

### Second Embodiment

A method of manufacturing a module according to a second embodiment based on the present invention is basically the same as the manufacturing method described in the first embodiment, but the condition of the CMP processing performed in step S4 is different. When the CMP processing is performed, slurry that contains H₂O₂ is used.

In the method of manufacturing a module according to the present embodiment, step S4 of performing the finishing processing is carried out under a processing condition where, at a first exposed surface, the removal rate of the material of the surface of a component 3 is higher than the removal rate of the material of a sealing resin layer 6a. More specifically, a condition that allows the removal rate of Si to be the highest among the respective removal rates of three kinds of materials, i.e. Cu, Si, and sealing resin, is selected as the condition of the CMP processing, and the CMP processing is performed thereunder. For example, the concentration of H₂O₂ in the slurry is manipulated as a parameter of the condition of the CMP processing. By appropriately setting the concentration of H₂O₂ in the slurry, the removal rate of Si is made the highest and Si surface 3u is depressed relative to the surface of the sealing resin layer. In other words, the Si surface 3u is structurally recessed or depressed relative to the resin surface 6a. This offset is achieved through the selective removal rate of the finishing process, where the silicon material is removed at a higher rate than the sealing resin.

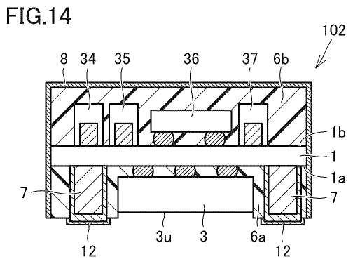

FIG. 14 illustrates the module obtained by the method of manufacturing a module according to the present embodiment.

The module according to the present embodiment is described with reference to FIG. 14.

Module 102 according to the present embodiment includes a substrate 1 having a first substrate surface 1a, a columnar electrode 7 as a conductive connection structure arranged on first substrate surface 1a, component 3 mounted over first substrate surface 1a, and sealing resin layer 6a provided so as to cover first substrate surface 1a, the side surfaces of columnar electrode 7, and the side surfaces of component 3. The end surface of columnar electrode 7 on the side farther from substrate 1 and the surface of component 3 on the side farther from substrate 1 are exposed through sealing resin layer 6a. A Si surface 3u as the surface of component 3 on the side farther from substrate 1 is depressed relative to the surface of sealing resin layer 6a on the side farther from substrate 1.

Module 102 illustrated in FIG. 14 includes components 34, 35, 36, and 37 mounted over a second substrate surface 1b. The component group presented here is merely an example and is not limited to this.

In module 102, columnar electrode 7 as the conductive connection structure includes a main body portion formed of a first material, and a covering portion formed of a second material so as to cover the side surfaces and the end surface of the main body portion. The main body portion and the covering portion may be formed of different materials. The covering portion is not limited to a single layer but may be made up of a plurality of layers. The covering portion may be, for example, a stacked structure of Au and Ni. In this case, firstly, Ni plating is performed on the side surfaces and the end surface of the main body portion, and then Au plating is performed thereon so as to cover the main body portion. Such a structure of columnar electrode 7 is merely an example and is not limited to the one described above.

The manufacturing method according to the present embodiment enables it to easily obtain a module with a structure in which Si surface 3u as the surface of component 3 on the side farther from substrate 1 is depressed relative to the surface of sealing resin layer 6a on the side farther from substrate 1.

It is assumed that the module according to the present embodiment is used by being incorporated into a certain set. This module can undergo a plurality of flow steps, which include incorporating the module into the set. In the module according to the present embodiment, Si surface 3u is depressed relative to the surface of sealing resin layer 6a, and thus, occurrence of a flaw on Si surface 3u in the plurality of flow steps is inhibited. In addition, since Si surface 3u of component 3 is depressed relative to the surface of sealing resin layer 6a, component 3 is hindered from getting damaged in each flow step.

Module 101 described in the first embodiment may employ the structure described in the present embodiment. That is, also in module 101 described in the first embodiment, the surface of component 3 on the side farther from substrate 1 may be depressed relative to the surface of sealing resin layer 6a on the side farther from substrate 1. By employing this structure, the effects described in the present embodiment can also be obtained together.

More than one of the above-described embodiments may be appropriately combined and employed.

The herein-disclosed foregoing embodiments are presented by way of illustration and example in all respects and are not to be taken by way of limitation. The scope of the present invention is defined by the claims and encompasses all changes within the purport and scope equivalent to the claims.

### Appendix 1

A method of manufacturing a module, the method comprising:
mounting a component including a Si layer over a first substrate surface of a substrate having the first substrate surface on which a conductive connection structure is arranged;
forming a sealing resin layer so as to cover the first substrate surface, the conductive connection structure, and the component;
forming a first exposed surface including respective portions where the conductive connection structure and the component are exposed through the sealing resin layer by collectively grinding away an upper surface of the conductive connection structure, an upper surface of the component, and an upper surface of the sealing resin layer by grinding processing;
performing finishing processing on the first exposed surface to decrease surface roughness Ra of the component; and
performing plating on a surface of the conductive connection structure at the first exposed surface.

### Appendix 2

The method of manufacturing a module according to Appendix 1, wherein performing the finishing processing includes performing CMP processing.

### Appendix 3

The method of manufacturing a module according to Appendix 1 or 2, wherein the surface roughness Ra of a surface of the component exposed through the sealing resin layer after completion of performing the finishing processing is 0.1 μm or less.

### Appendix 4

The method of manufacturing a module according to any one of Appendices 1 to 3, wherein the surface roughness Ra of the upper surface of the sealing resin layer after completion of performing the finishing processing is 0.1 μm or less.

### Appendix 5

The method of manufacturing a module according to any one of Appendices 1 to 4, wherein the finishing processing is performed under a processing condition where, at the first exposed surface, a removal rate of a material of a surface of the component is higher than a removal rate of a material of the sealing resin layer.

### Appendix 6

A module comprising:
a substrate having a first substrate surface;
a conductive connection structure arranged on the first substrate surface;
a component mounted over the first substrate surface; and
a sealing resin layer provided so as to cover the first substrate surface, a side surface of the conductive connection structure, and a side surface of the component, wherein
an end surface of the conductive connection structure on a side farther from the substrate and a surface of the component on the side farther from the substrate are exposed through the sealing resin layer, and the surface of the component on the side farther from the substrate is depressed relative to a surface of the sealing resin layer on the side farther from the substrate.

### Appendix 7

A module comprising:
a substrate having a first substrate surface;
a conductive connection structure arranged on the first substrate surface;
a component mounted over the first substrate surface; and
a sealing resin layer provided so as to cover the first substrate surface, a side surface of the conductive connection structure, and a side surface of the component, wherein
an end surface of the conductive connection structure on a side farther from the substrate and a surface of the component on the side farther from the substrate are exposed through the sealing resin layer, and surface roughness Ra of the surface of the component on the side farther from the substrate is 0.1 μm or less.

### Appendix 8

The module according to Appendix 7, wherein the surface of the component on the side farther from the substrate is depressed relative to a surface of the sealing resin layer on the side farther from the substrate.

### REFERENCE SIGNS LIST

1 substrate; 1a first substrate surface; 1b second substrate surface; 3 component; 3a Si layer; 3u Si surface; 6a, 6b sealing resin layer; 7 columnar electrode; 8 shield film; 12 plating film; 14 bump; 15 depressed portion; 31, 32, 33, 34, 35, 36, 37 component; 41 first exposed surface; 101, 102 module.

1. A method of manufacturing a module, the method comprising:
mounting a component including a silicon (Si) layer over a first substrate surface of a substrate, the first substrate surface having a conductive connection structure arranged thereon;
forming a sealing resin layer covering the first substrate surface, the conductive connection structure, and the component;
forming a first exposed surface by grinding the sealing resin layer, the conductive connection structure, and the component, until respective portions of the conductive connection structure and the component are exposed through the sealing resin layer;
finish processing the first exposed surface to decrease surface roughness Ra of the component; and
plating a surface of the conductive connection structure at the first exposed surface while the Si layer remains exposed and free of a resist film.

2. The method of manufacturing a module according to claim 1, wherein finish processing includes performing chemical mechanical polishing (CMP) processing.

3. The method of manufacturing a module according to claim 1, wherein the surface roughness Ra of a surface of the component exposed through the sealing resin layer after completion of finish processing is 0.1 μm or less.

4. The method of manufacturing a module according to claim 1, wherein the surface roughness Ra of the upper surface of the sealing resin layer after completion finish processing is 0.1 μm or less.

5. The method of manufacturing a module according to claim 1, wherein finish processing is performed under a processing condition where, at the first exposed surface, a removal rate of a material of a surface of the component is higher than a removal rate of a material of the sealing resin layer.

6. The method of manufacturing a module according claim 5, further comprising manipulating a concentration of H₂O₂ in a slurry during the finish processing to depress the Si layer relative to the sealing resin layer.

7. The method of manufacturing a module according claim 1, wherein the conductive connection structure includes a columnar electrode.

8. A module comprising:
a substrate having a first substrate surface;
a conductive connection structure arranged on the first substrate surface;
a component mounted over the first substrate surface; and
a sealing resin layer covering the first substrate surface, a side surface of the conductive connection structure, and a side surface of the component, wherein
an end surface of the conductive connection structure on a side farther from the substrate and a surface of the component on the side farther from the substrate are exposed through the sealing resin layer, and
the surface of the component on the side farther from the substrate is depressed relative to a surface of the sealing resin layer on the side farther from the substrate.

9. The module according claim 8, wherein the surface of the component on the side farther from the substrate has a surface roughness Ra of 0 is 0.1 μm or less.

10. The module according claim 8, wherein the component is an integrated circuit.

11. The module according claim 8, further comprising a shield film covering side surfaces of the sealing resin layer and the substrate.

12. The module according claim 8, further comprising a second component mounted over a second substrate surface opposite the first substrate surface.

13. The module according claim 12, further comprising a second sealing resin layer covering the second component.

14. The module according claim 8, wherein the conductive connection structure includes a main body portion formed of a first material and a covering portion formed of a second material covering an end surface of the main body portion.

15. A module comprising:
a substrate having a first substrate surface;
at least two conductive connection structures arranged on the first substrate surface;
an electronic component mounted over the first substrate surface; and
a sealing resin layer provided so as to cover the first substrate surface, a side surface of the conductive connection structure, and a side surface of the electronic component, wherein
an end surface of each of the at least two conductive connection structures on a side farther from the substrate and a surface of the electronic component on the side farther from the substrate are exposed through the sealing resin layer, and
surface roughness Ra of the surface of the electronic component on the side farther from the substrate is 0.1 μm or less.

16. The module according to claim 15, wherein the surface of the electronic component on the side farther from the substrate is depressed relative to a surface of the sealing resin layer on the side farther from the substrate.

17. The module according to claim 15, wherein the electronic component includes one of a surface acoustic wave device, a bulk acoustic wave device, a passive integrated device.

18. The module according to claim 15, further comprising a shield film covering side surfaces of the sealing resin layer and the substrate.

19. The module according to claim 15, further comprising a plating film disposed only on end surfaces of the at least two conductive connection structures exposed through the sealing resin layer.

20. The module of claim 15, further comprising a shield film covering a side surface of the sealing resin layer and a side surface of the substrate, wherein the shield film is electrically connected to a ground potential via at least one of the at least two conductive connection structures.
